(19) United States
(12) Patent Application Publication
(10) Pub. No.: US 2021/0365603 A1
(43) Pub. Date: Nov. 25, 2021

(54) ARTIFICIAL INTELLIGENCE SYSTEMS AND METHODS FOR INTERIOR FURNISHING

(71) Applicant: Ke.com (Beijing) Technology Co., Ltd., Beijing (CN)

(72) Inventors: Xiaodong GU, Beijing (CN); Cihui PAN, Beijing (CN); Chenglin Liu, Beijing (CN); Yan ZHOU, Beijing (CN)

(73) Assignee: Ke.com (Beijing) Technology Co., Ltd., Beijing (CN)

(21) Appl. No.: 17/324,023

(22) Filed: May 18, 2021

(30) Foreign Application Priority Data
May 19, 2020 (CN) 202010427543.7
Jun. 18, 2020 (CN) 202010560309.1
Jun. 18, 2020 (CN) 202010561583.0

(51) Int. Cl. G06F 30/13; G06N 3/08

(52) U.S. Cl. CPC G06F 30/13; G06N 3/08

(57) ABSTRACT

Systems and methods for generating a furnishing plan for a property are disclosed. An exemplary system includes a communication interface configured to receive a floor plan of the property, at least one candidate furnishing item to be placed in the property and attributes of the candidate furnishing item, and a first neural network model. The system further includes at least one processor configured to generate a mask based on the floor plan of the property and the attributes of the candidate furnishing item and generate proposals for placing the candidate furnishing item in the property based on the mask and the attributes of the candidate furnishing item. The at least one processor is further configured to determine a probability for each proposal using the first neural network model. The first neural network model is trained with a position query algorithm; select one or more proposals having the highest probabilities. The at least one processor is also configured to generate the furnishing plan for the property based on the one or more proposals.

### CROSS-REFERENCE OF RELATED APPLICATIONS

This application hereby claims the benefits of priority to Chinese Application No. 202010427543.7, filed on May 19, 2020, Chinese Application No. 202010560309.1, filed Jun. 18, 2020, and Chinese Application No. 202010561583.0, filed Jun. 18, 2020, all of which are hereby incorporated by reference in their entireties.

### TECHNICAL FIELD

The present disclosure relates to systems and methods for interior furnishing, and more particularly, to artificial intelligence systems and methods for automatically generating room furnishing plans and evaluating the room furnishing plans.

### BACKGROUND

Property owners may need assistance with interior furnishing at various occasions, such as, when they would like to furnish a new property, refurnish a space, or stage a space before putting the property on the market. One challenge with interior furnishing has been imposed by the time and efforts consumed for a property owner to learn the home improvement rules used by professionals, to search for proper materials, and to repeatedly communicate with professional designers. Accordingly, the time cost for furnishing a space is extremely high.

Another challenge comes from the difficulty to assess how the furnishing plan may adapt to the actual space before the plan is executed. For example, when a person is browsing online to search for a piece of furniture for his living room, while the furniture may be well depicted with multiple images or videos, the user could not visualize how it may fit into his living room. It is usually not clear to the property owner until the piece of furniture is purchased and placed into the living room that the dimensions of the piece may not fit or the style of the piece does not match with other decorations in the room.

Therefore, interior furnishing can greatly benefit from intelligently generated furnishing plans and the ability to evaluate such plans before the design will be implemented in that space. To address these needs, embodiments of the disclosure provide artificial intelligence systems and methods for generating and evaluating interior furnishing plans.

### SUMMARY

Embodiments of artificial intelligence systems, methods, computer-readable medium for generating a furnishing plan for a property are disclosed.

In one aspect, an exemplary system includes a communication interface configured to receive a floor plan of the property, at least one candidate furnishing item to be placed in the property and attributes of the candidate furnishing item, and a first neural network model. The system further includes at least one processor configured to generate a mask based on the floor plan of the property and the attributes of the candidate furnishing item and generate proposals for placing the candidate furnishing item in the property based on the mask and the attributes of the candidate furnishing item. The at least one processor is further configured to determine a probability for each proposal using the first neural network model. The first neural network model is trained with a position query algorithm; select one or more proposals having the highest probabilities. The at least one processor is also configured to generate the furnishing plan for the property based on the one or more proposals.

In another aspect, an exemplary computer-implemented method includes receiving, by a communication interface, a floor plan of the property, at least one candidate furnishing item to be placed in the property and attributes of the candidate furnishing item, and a first neural network model. The method further includes generating, by at least one processor, a mask based on the floor plan of the property and the attributes of the candidate furnishing item and generating proposals for placing the candidate furnishing item in the property based on the mask and the attributes of the candidate furnishing item. The method also includes determining, by the at least one processor, a probability for each proposal using the first neural network model. The first neural network model is trained with a position query algorithm. The method additionally includes selecting one or more proposals having the highest probabilities and generating the furnishing plan for the property based on the one or more proposals.

In yet another aspect, a non-transitory computer-readable medium has stored thereon computer instructions, when executed by at least one processor, perform a method for generating a furnishing plan for a property. The method includes receiving a floor plan of the property, at least one candidate furnishing item to be placed in the property and attributes of the candidate furnishing item, and a first neural network model. The method further includes generating a mask based on the floor plan of the property and the attributes of the candidate furnishing item and generating proposals for placing the candidate furnishing item in the property based on the mask and the attributes of the candidate furnishing item. The method also includes determining a probability for each proposal using the first neural network model. The first neural network model is trained with a position query algorithm. The method additionally includes selecting one or more proposals having the highest probabilities and generating the furnishing plan for the property based on the one or more proposals.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a schematic diagram of an exemplary three-dimensional view of an interior of a property, according to embodiments of the disclosure.

FIG. 2 illustrates an exemplary artificial intelligence system for interior furnishing, according to embodiments of the disclosure.

FIG. 3 is a block diagram of an exemplary interior furnishing device, according to embodiments of the disclosure.

FIG. 4 is a flowchart of an exemplary method for generating a furnishing plan for an interior space using a neural network, according to embodiments of the disclosure.

FIGS. 5A-5E illustrate a process of placing furnishing items in an interior space, according to embodiments of the disclosure.

FIG. 6 is a flowchart of an exemplary method for generating a furnishing plan for an interior space using data migration, according to embodiments of the disclosure.

FIG. 7 is a flowchart of an exemplary method for matching structural features extracted from an interior space, according to embodiments of the disclosure.

FIG. 8 is a flowchart of an exemplary method for evaluating a furnishing plan for an interior space, according to embodiments of the disclosure.

FIG. 9 is a flowchart of an exemplary method for generating a rationality score for a furnishing plan, according to embodiments of the disclosure.

FIG. 10 is a flowchart of an exemplary method for generating a distribution score for a furnishing plan, according to embodiments of the disclosure.

FIG. 11 is a flowchart of an exemplary method for generating a functionality score for a furnishing plan, according to embodiments of the disclosure.

FIG. 12 illustrates schematic diagrams of two different furnishing plans for a same interior space, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

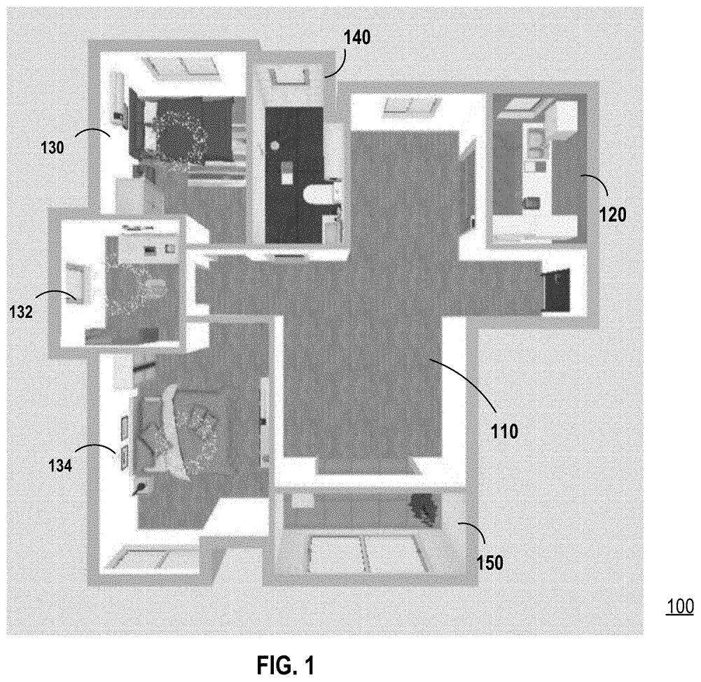

FIG. 1 illustrates a schematic diagram of an exemplary three-dimensional (3D) view of an interior of a property 100 (hereafter “property 100”), according to embodiments of the disclosure. In some embodiments, property 100 may be a residential property such as a house, an apartment, a townhouse, a garage, or a commercial property such as a warehouse, an office building, a hotel, a museum, and a store, etc. As shown in FIG. 1, the three-dimensional view virtually recreates property 100 including its layout (e.g., the framing structures that divide the property into several rooms such as walls and counters), finishing (e.g., kitchen/bathroom cabinets, bathtub, island, etc.), fixtures installed (e.g., appliances, window treatments, chandeliers, etc.), and furniture and decorations (e.g., beds, desks, tables and chairs, sofas, TV stands, bookshelves, wall paintings, mirrors, plants, etc.)

In some embodiments, property 100 may include multiple rooms or functional spaces separated by interior walls. For example, as shown in FIG. 1, property 100 may include a living room 110, a kitchen 120, three bedrooms 130, 132, and 134, a bathroom 140, and a balcony 150, etc.

Consistent with embodiments of present disclosure, property 100 may be a finished space that needs interior furnishing. Interior furnishing of property 100 may include furnishing and decorating the interior space of the property. In some embodiments, property 100 is empty and entirely unfurnished. In some other embodiments, property 100 may be partially furnished. For example, as shown in FIG. 1, among the rooms, living room 110 has not been furnished yet, and the remaining six rooms or functional spaces have been furnished. Therefore, the only room waiting to be furnished is living room 110.

Sometimes, property owners may want to refurnish/redecorate the respective spaces, to accommodate different use or style. For example, bedroom 130 may be converted to a nursery in expectation of a newborn, so that the bed may be replaced with a crib and a changing table, and the room may be decorated with a cartoon theme. As another example, the property owner may have a change of taste and would like to replace European style furniture with modern furniture. Sometimes, properties may be staged with staging furniture and decorative pieces before conducting open houses.

Furnishing/refurnishing a property, or a part of the property, is a time consuming and high-cost project. Property owners do not want to wait until it is completed to find that it is not quite the effect they have imagined and desired. It would be a hassle to make any adjustment afterwards. For example, when a piece of furniture is purchased and delivered, it is difficult to return or change it. The present disclosure provides artificial intelligence systems and methods for generating an interior furnishing plan for a space (e.g., property 100) and providing an evaluation of the same, so that the user (e.g., a property owner or an interior designer) could effectively and efficiently furnish the space by following the recommended furnishing plan. In some embodiments, the disclosed systems and methods may use neural networks to intelligently generate and/or evaluate the furnishing plans based on the attributes of the actual space and attributes of the furnishing items.

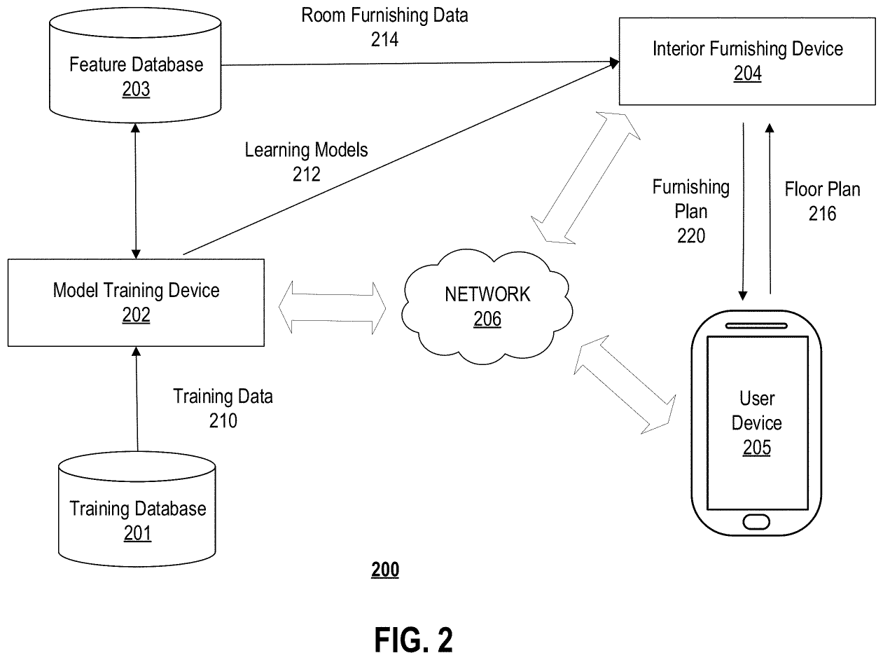

FIG. 2 illustrates an exemplary artificial intelligence interior furnishing system 200 (referred to as “system 200” hereafter), according to some embodiments of the disclosure. In some embodiments, system 200 may be configured to provide interior furnishing plans for an actual space. For example, system 200 may provide a furnishing plan based on a floor plan of an interior space.

In some embodiments, system 200 may generate and/or evaluate a furnishing plan using a machine learning network. As shown in FIG. 2, system 200 may include components for performing two phases, a training phase and a learning phase. To perform the training phase, system 200 may include a training database 201 for storing training data 210 and a model training device 202 for training learning models 212. In some embodiments, learning models 212 may include learning models for generating furnishing plans and learning models for evaluating the furnishing plans.

In some embodiments, model training device 202 may additionally or alternatively extract structural features and labeled furnishing data associated with the structural features from training data 210 in training database 201 and store the extracted data as room furnishing data 214 in a feature database 203. For example, each room furnishing data 214 may include the structural features of a previously furnished room and the furnishing data of that furnished room. In some embodiments, room furnishing data 214 may be stored in sub-databases according to room types. For example, each sub-database in feature database 203 may correspond to one room type, e.g., living room, bedroom, balcony, etc.

To perform the learning phase, system 200 may include interior furnishing device 204 for intelligently generate/evaluate furnishing plans using trained learning models 212 and/or room furnishing data 214. In some embodiments, system 200 may include more or less of the components shown in FIG. 2. For example, when learning models 212 and/or room furnishing data 214 are pre-trained and provided, system 200 may include only interior furnishing device 204.

In some embodiments, system 200 may optionally include a network 206 to facilitate the communication among the various components of system 200, such as databases 201, 203, and devices 202, 204, and user device 205. For example, network 206 may be a local area network (LAN), a wireless network, a cloud computing environment (e.g., software as a service, platform as a service, infrastructure as a service), a client-server, a wide area network (WAN), etc. In some embodiments, network 206 may be replaced by wired data communication systems or devices.

In some embodiments, the various components of system 200 may be remote from each other or in different locations, and be connected through network 206 as shown in FIG. 2. In some alternative embodiments, certain components of system 200 may be located on the same site or inside one device. For example, training database 201 and/or feature database 203 may be located on-site with or be part of model training device 202. As another example, model training device 202 and interior furnishing device 204 may be inside the same computer or processing device. Although illustrated as one single device, in some embodiments, interior furnishing device 204 may be implemented with two separate devices for generating furnishing plans and for evaluation furnishing plans, respectively.

As shown in FIG. 2, model training device 202 may communicate with training database 201 to receive one or more sets of training data 210. Model training device 202 may use the training data received from training database 201 to train a plurality of learning models (e.g., trained learning models 212). Trained learning models 212 may include learning models for generating furnishing plans, and learning models for evaluating furnishing plans, and the like. Learning models 212 may be trained using training data 210 stored in training database 201. Model training device 202 may further extract structural features and labeled furnishing data from the training data received from training database 201 and store them in feature database 203.

In some embodiments, the training phase may be performed “online” or “offline.” An “online” training refers to performing the training phase contemporarily with the learning phase. An “online” training may have the benefit to obtain a most updated learning models based on the training data that is then available. However, an “online” training may be computational costive to perform and may not always be possible if the training data is large and/or the models are complicate. Consistent with the present disclosure, an “offline” training is used where the training phase is performed separately from the learning phase. Learned models 212 may be trained offline and saved and reused for assisting interior design.

Model training device 202 may be implemented with hardware specially programmed by software that performs the training process. For example, model training device 202 may include a processor and a non-transitory computer-readable medium. The processor may conduct the training by performing instructions of a training process stored in the computer-readable medium. Model training device 202 may additionally include input and output interfaces to communicate with training database 201, feature database 203, network 206, and/or a user interface (not shown). The input and output interfaces may include a user interface used for selecting sets of training data, adjusting one or more parameters of the training process, selecting or modifying a framework of the learning model, and/or manually or semi-automatically providing ground-truth associated with training data 210.

Interior furnishing device 204 may receive trained learning models 212 from model training device 202. Interior furnishing device 204 may additionally or alternatively receive room furnishing data 214 from feature database 203. Trained learning models 212 and/or room furnishing data 214 may be used by interior furnishing device 204 to generate a floor plan for a new interior space, such as a room of property 100. In some embodiments, interior furnishing device 204 may further evaluate the floor plan using trained learning models 212, such as to calculate an evaluation score for the floor plan. The floor plan may be recommended to a user based on its evaluation score.

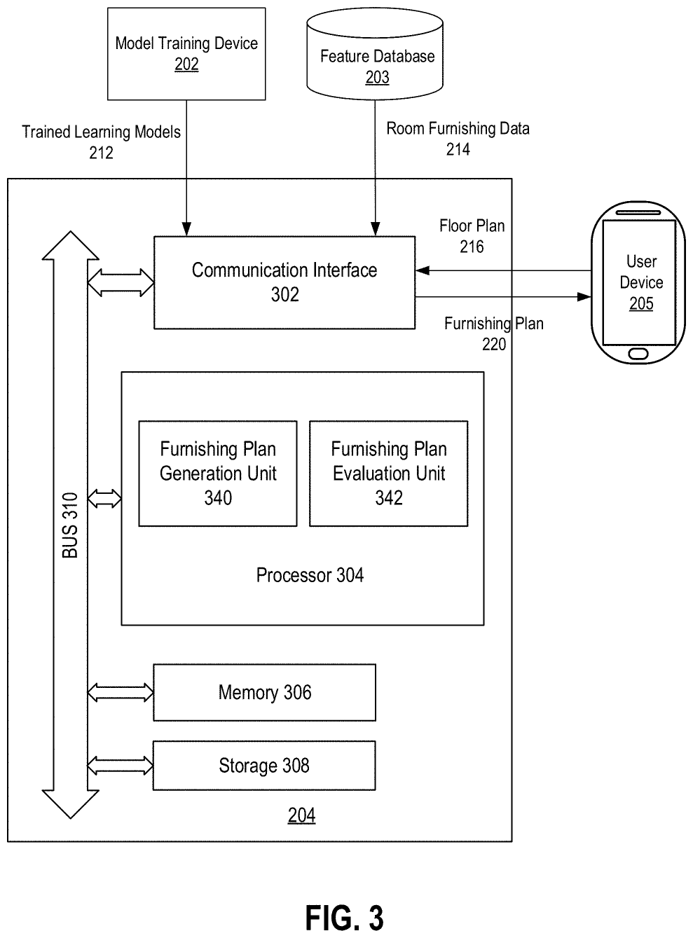

Interior furnishing device 204 may include a processor and a non-transitory computer-readable medium (discussed in detail in connection with FIG. 3). The processor may perform instructions of a sequence of interior furnishing processes stored in the medium. Interior furnishing device 204 may additionally include input and output interfaces to communicate with model training device 202, feature database 203, user device 205, network 206, and/or a user interface (not shown). The user interface may be used for receiving floor plan 216 of a property to be furnished. The user interface may further provide a furnishing plan 220 to user device 205 including a suggested placing of furnishing items in the property.

In some embodiments, user device 205 may be a cellular device or a smart phone, a personal digital assistant (PDA), a laptop computer, a tablet device and a wearable device, which may provide network connection and process resources to communicate with interior furnishing device 204 through network 206. User device 205 may also include, for example, an on-board computing system or customized hardware. User device 205 may also run designated service applications such as interior furnishing applications to provide design assistance and suggestions to the user.

User device 205 may include an interface for user interaction. For example, the interface may be a touchscreen or a keyboard (physical keyboard or soft keyboard) for the user to input data to user device 205. In some embodiments of the present disclosure, user may send information of an interior space along with furnishing preferences to interior furnishing device 204, via user device 205. For example, the user may send images or other data of a room to interior furnishing device 204, which then obtains or otherwise generates floor plan 216 of the room based on the data. The user may specify candidate furnishing items to be placed in the interior space and preferred attributes of such furnishing items. The user may also specify furnishing rules, such as a bed must be against a wall, sofa must have a front area, or a mirror must be facing a window, etc. In some embodiments of the present disclosure, interior furnishing device 204 may provide a furnishing plan 220 as a suggested way to furnish the interior space to user device 205.

User device 205 may display furnishing plan 220 to the user through a display. For example, user device 205 may display a rendered view of the user provided interior space with suggested furniture and decorations placed therein according furnishing plan 220. As nonlimiting examples, the display may be a Liquid Crystal Display (LCD), a Light Emitting Diode Display (LED), a plasma display, or any other type of display. In some embodiments, the display may be integrated with the user interface. For example, the display may include a touch-sensitive material that is substantially rigid, such as Gorilla Glass™, or substantially pliable, such as Willow Glass™.

FIG. 3 is a block diagram of an exemplary interior furnishing device 204, according to embodiments of the disclosure. In some embodiments, interior furnishing device 204 may be implemented by a physical server or a service in the cloud. In some other embodiments, interior furnishing device 204 may be implemented by a computer or a consumer electronic device such as a mobile phone, a pad, or a wearable device. As shown in FIG. 3, interior furnishing device 204 may include a communication interface 302, a processor 304, a memory 306, a storage 308, and a bus 310. In some embodiments, interior furnishing device 204 may have different modules in a single device, such as an integrated circuit (IC) chip (implemented as an application-specific integrated circuit (ASIC) or a field-programmable gate array (FPGA)), or separate devices with dedicated functions. Components of interior furnishing device 204 may be in an integrated device, or distributed at different locations but communicate with each other through a network (not shown). The various components of interior furnishing device 204 may be connected to and communicate with each other through bus 310.

Communication interface 302 may send data to and receive data from components such as model training device 202, feature database 203, and user device 205 via direct communication links, a Wireless Local Area Network (WLAN), a Wide Area Network (WAN), wireless communication networks using radio waves, a cellular network, and/or a local wireless network (e.g., Bluetooth or WiFi), or other communication methods. In some embodiments, communication interface 302 can be an integrated services digital network (ISDN) card, cable modem, satellite modem, or a modem to provide a data communication connection. As another example, communication interface 302 can be a local area network (LAN) card to provide a data communication connection to a compatible LAN. Wireless links can also be implemented by communication interface 302. In such an implementation, communication interface 302 can send and receive electrical, electromagnetic or optical signals that carry digital data streams representing various types of information via a network.

Consistent with some embodiments, communication interface 302 may receive floor plan 216 provided via user device 205 or a floor plan database and other furnishing preferences. For example, communication interface 302 may receive candidate furnishing items to be placed in the interior space and attributes of such furnishing items. Consistent with the disclosure, furnishing items may include furniture pieces such as sofas, beds, tables, chairs, cabinets, etc., fixtures such as chandeliers and window treatments, and decorative items such as pictures, plants, sculptures, mirrors, etc. The candidate furnishing items may be specified by the user or automatically selected by an external device based on factors such as user preference, user profile, and attributes of the interior space to be furnished. The attributes of each furnishing item may include the size and shape of the item, as well as furnishing rules associated with the item, such as whether the furnishing item must be placed against a wall, whether the furnishing item requires a front area, and whether the furnishing item can be placed within the front area of another item, etc.

In some embodiments of the present disclosure, interior furnishing device 204 may provide a furnishing plan 220 as a suggested way to furnish the interior space to user device 205. In some further embodiments, communication interface 302 may also receive trained learning models 212 from model training device 202 and room furnishing data 214 from feature database 20. Communication interface 302 may provide the received information or data to memory 306 and/or storage 308 for storage or to processor 304 for processing.

Processor 304 may include any appropriate type of general-purpose or special-purpose microprocessor, digital signal processor, or microcontroller. Processor 304 may be configured as a separate processor module dedicated to interior design. Alternatively, processor 304 may be configured as a shared processor module for performing other functions related to or unrelated to interior design. For example, the interior design application is just one application installed on a versatile device.

As shown in FIG. 3, processor 304 may include multiple modules, such as a furnishing plan generation unit 340 and a furnishing plan evaluation unit 342, and the like. These modules (and any corresponding sub-modules or sub-units) can be hardware units (e.g., portions of an integrated circuit) of processor 304 designed for use with other components or to execute part of a program. The program may be stored on a computer-readable medium (e.g., memory 306 and/or storage 308), and when executed by processor 304, it may perform one or more functions. Although FIG. 3 shows units 340-344 all within one processor 304, it is contemplated that these units may be distributed among multiple processors located near or remotely with each other.

Memory 306 and storage 308 may include any appropriate type of mass storage provided to store any type of information that processor 304 may need to operate. Memory 306 and storage 308 may be a volatile or non-volatile, magnetic, semiconductor, tape, optical, removable, non-removable, or other type of storage device or tangible (i.e., non-transitory) computer-readable medium including, but not limited to, a ROM, a flash memory, a dynamic RAM, and a static RAM. Memory 306 and/or storage 308 may be configured to store one or more computer programs that may be executed by processor 304 to perform image processing, interior design suggestion, and view rendering as disclosed herein. For example, memory 306 and/or storage 308 may be configured to store program(s) that may be executed by processor 304 to generate a furnishing plan to furnish an interior space, and/or evaluate a furnishing plan.

Memory 306 and/or storage 308 may be further configured to store information and data used by processor 304. For instance, memory 306 and/or storage 308 may be configured to store various data received by interior furnishing device 204, such as trained learning models 212, room furnishing data 214, floor plan 216, and other inputs such as candidate furnishing items and their attributes. Memory 306 and/or storage 308 may also be configured to store intermediate data generated by processor 304, such as attributes of furnishing items, structural features extracted from floor plan 216, masks generated based on floor plan and existing furnishing items, and proposals for placing the furnishing items. The various types of data may be stored permanently, removed periodically, or disregarded immediately after it is processed. For example, the candidate furnishing items can be saved in a list_furnitures list in memory 306 and/or storage 308.

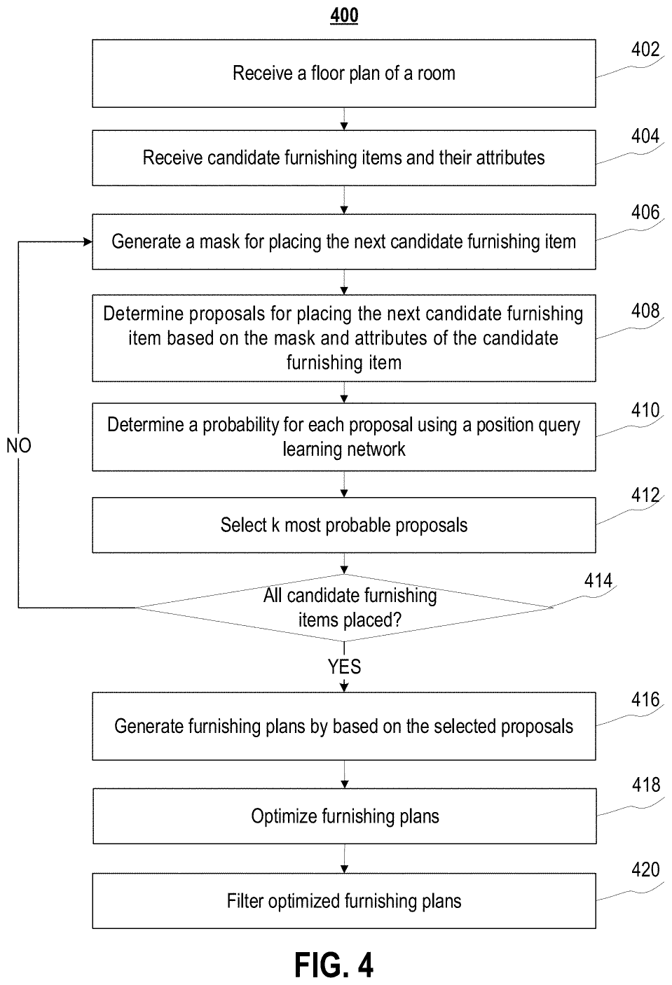

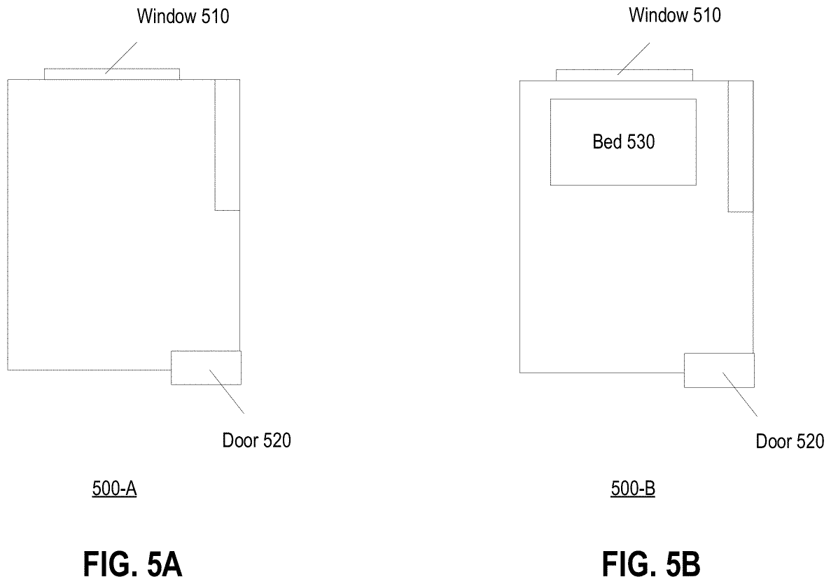

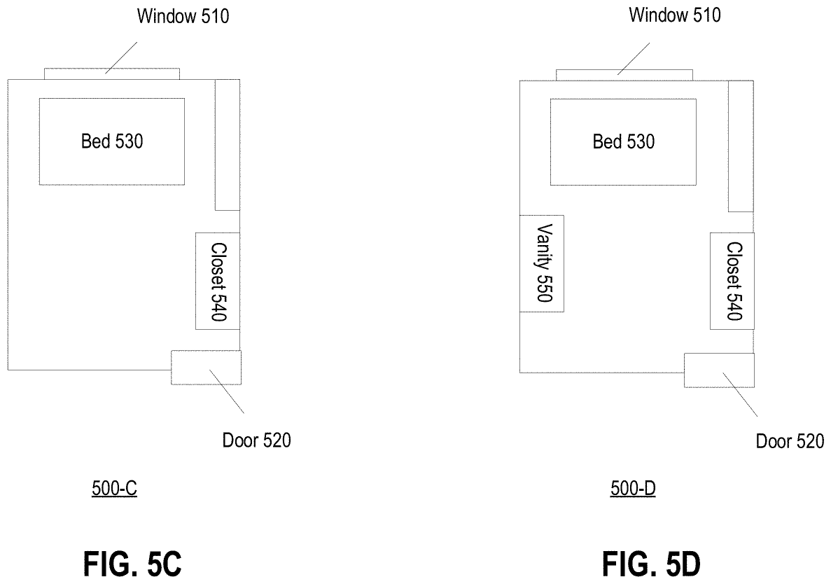

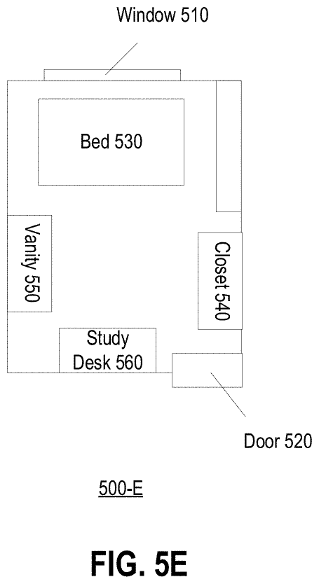

FIG. 4 is a flowchart of an exemplary method 400 for generating a furnishing plan for an interior space using a neural network, according to embodiments of the disclosure. In some embodiments, method 400 may be performed by processor 304 of interior furnishing device 204, e.g., furnishing plan generation unit 340. Method 400 may include steps 402-420 as described below. It is to be appreciated that some of the steps may be optional to perform the disclosure provided herein. Further, some of the steps may be performed simultaneously, or in a different order than shown in FIG. 4. FIGS. 5A-5E illustrate a process of placing furnishing items in an interior space, according to embodiments of the disclosure. For description purpose, method 400 will be described together with FIGS. 5A-5E. Method 500, however, can be implemented for furnishing of other spaces of a property.

In step 402, interior furnishing device 204 receives a floor plan (e.g., floor plan 216) of a target room in a property. In some embodiments, the floor plan may be provided by user device 205. In some other embodiments, the floor plan may be generated interior furnishing device based on information provided by user device 205 or generated by an external device and obtained by interior furnishing device 205. The target room can be a bedroom, a living room, a bathroom, etc. For example, the target room can be living room 110 in property 100. The floor plan can be generated by CAD modeling tools or can be a vector diagram. The floor plan includes multiple elements that can be used to obtain the corresponding structural features. The structural features may include, e.g., wall distribution data, load-bearing wall distribution data, door and window distribution data, area data, floor height data, location coordinate data, etc. In some embodiments, if the room is partially furnished, interior furnishing device 204 also receives one or more existing furnishing items and the attributes of these furnishing items.

In step 404, interior furnishing device 204 receives one or more candidate furnishing items to be placed in the room. For example, a furnishing item (existing or candidate furnishing item) may include, e.g., furniture, fixtures, appliances, and decorations, etc. The attributes of the furnishing item may include, e.g., item category, item style, item size, item placement attributes, etc. For example, item placement attributes may include the placement and orientation of the item, whether the item must be against the wall, whether the item has a front area, whether the item can be placed in the front area of other items, etc.

In steps 406-414, interior furnishing device 204 then generate multiple proposals for placing the candidate furnishing items in the room, based on the floor plan and attributes of the existing and candidate furnishing items, as well as predetermined furnishing rules. The furnishing items are placed one by one and the loop of steps 406-414 is repeated for each candidate furnishing item, until all the candidate furnishing items are placed.

For example, FIGS. 5A-5E illustrate a process of placing furnishing items in an interior space, according to embodiments of the disclosure. 500-A shows an empty room that is unfurnished. The room is rectangular in shape and has a window 510 on one wall and a door 520 next to a corner. Therefore, the structural data of the target room includes a door, a window, and four walls, etc. The furnishing items to be placed the target room include a bed 530, a closet 540, a closet 540, a vanity 550, and a study desk 560. Accordingly, a list of candidate furnishing items list_furnitures can be generated as list_furnitures=[“bed”, “closet”, “vanity”, “study desk”].

500-B shows that the first furnishing item, bed 530, is placed next to window 510. 500-C shows that the second furnishing item, closet 540, is placed near door 520 and against a wall. 500-D shows the third furnishing item, vanity 550, is placed against another wall opposite to the wall of closet 540. 500-E shows the placement of the final furnishing item, study desk 560, against the wall opposite to the wall having window 510 and near door 520. Method 400 may repeat steps 406-414 for each of items 530-560 and place them into the room one by one. After a candidate furnishing item is placed, in the next iteration, it will be treated as an existing furnishing item.

In step 406, interior furnishing device 204 generates a mask for placing the next candidate furnishing item. The mask may be generated using structural features associated with the floor plan, the attributes of the existing furnishing items already placed in the target room, and the attributes of the candidate furnishing item currently being placed. The mask is an image that has the same image size (e.g., number of pixels) as the floor plan of the target room. The mask reflects the structural features of the floor plan and furnishing items already placed in the floor plan. The mask also takes into consideration attributes of the current candidate furnishing item to be placed. In some embodiments, the value of each pixel in the mask takes a binary value, e.g., either 0 or 255. For example, if the value of a certain pixel is 0, the corresponding position is available for receiving the candidate furnishing item. Otherwise, if the value of a certain pixel is 255, the corresponding position is either occupied by an existing furnishing item or in a front area of a furnishing item, and thus not available for receiving the candidate furnishing item.

In step 408, interior furnishing device 204 determines multiple proposals for placing the next candidate furnishing item based on the mask and attributes of the candidate furnishing item. Each proposal defines the placement position and orientation of the candidate furnishing item. The orientation of a furnishing item specifies which direction the item faces, e.g., up, down, right, or left, or alternatively, north, south, east, or west. In some embodiments, interior furnishing device 204 selects discrete pixels in the mask that have value 0, and generates initial proposals for placing the candidate furnishing item at the selected discrete pixels. For example, the gravity center or geometric center of the candidate furnishing item can be positioned at each of those discrete pixels.

In some embodiments, the initial proposals may be screened using predetermined furnishing rules. The predetermined furnishing rules may include various types of rules, such as no overlapping between furnishing items, no wall penetration, no blocking path rules, etc. The furnishing rules are used to screen the proposals. Proposals that can cause unrealistic or inconvenient designs such as crossing walls, overlapping with placed items, blocking the way, etc. will be removed.

In some embodiments, the mask, attributes of the candidate furnishing item, and the predetermined furnishing rules may collectively allow multiple possible placements of the candidate item in the floor plan. In that case, interior furnishing device 204 will determine multiple proposals including, e.g., a first proposal that places the candidate furnishing item at a first position and first orientation, and a second proposal that places the candidate furnishing item at a second position and second orientation. For example, while 500-C shows the candidate furnishing item, closet 540, is placed against the right wall and next to door 520, it can be alternatively placed against the left wall or the bottom wall on the other side of door 520. All these potential placements may be kept as viable proposals in step 408.

In step 410, interior furnishing device 204 uses a neural network model to determine a placement probability for each proposal. Different types of neural network models, such as a graphical neural network GNN (Graphical Neural Network) model, can be used. In some embodiments, the GNN network can be trained based on a fixed-point query algorithm (Position Query). The GNN model outputs a probability that the candidate furnishing item will in fact be placed at the position and orientation as defined by each proposal, given the floor plan and the existing furnishing items.

The neural network may be pre-trained, e.g., by model training device 202, using training samples generated from furnished rooms. For example, furnishing items may be partially removed from a furnished room to create training samples. The removed furnishing items may be treated as “candidate furnishing items” for training purpose. Structure data of the floor plan, attributes of the furnishing items remaining in the furnished room, and attributes of removed items (candidate furnishing items) may be generated as training data. The actual placement of the removed furnishing items in the furnished rooms are used as ground truth for training the neural network.

In step 414, interior furnishing device 204 selects K most probable proposals based on the determined placement probabilities. In some embodiments, the multiple proposals are sorted from the largest placement probability to the smallest. One or more (e.g., K) proposals with placement probabilities at the head of the ranking may be selected. The K proposals include the proposal with the highest probability and one or more proposals having probabilities differing from the highest probability with less a threshold difference. The selected proposals are referred to as recommended proposals. The number K can be set any suitable integer, such as 1, 2, 3, etc. In some embodiments, the number K can be determined based on the distribution of the probabilities. For example, if after ranking the probabilities, the 2^{nd} and 3^{rd} proposals have probabilities differing from the highest probability with a very small difference, and the 4^{th} proposal has a probability much lower than the top 3, K may be set as 3.

In some embodiments, at the end of each iteration, the K selected proposals are added to a list of selected proposals selected_proposals. The current candidate furnishing item is placed and therefore removed from the list list_furnitures. For each of the selected proposals, interior furnishing device 204 will treat the candidate furnishing item as an existing furnishing item placed according to that proposal and run steps 406-414 to place the next candidate furnishing item in list_furnitures. For example, after bed 530 is placed according to a selected proposal illustrated in 500-B, bed 530 is removed from list_furnitures and interior furnishing device 204 repeats steps 406-414 to place the next candidate furnishing item, closet 540.

In step 416, after all candidate furnishing items are placed, interior furnishing device 204 generates one or more furnishing plans for the target room based on the recommended proposals. In some embodiments, a furnishing plan may include a placement diagram for showing the placement and orientation of the furnishing items such as tables, beds, appliances, and decorations in the target room. In some embodiments, the furnishing plans are generated based on the recommended proposals, association relationships between the recommended proposals, and structural data of the floor plan. During each iteration of steps 406-414, each recommended proposal is used as the basis to generate K recommended proposals in the next iteration for the next candidate furnishing item. Therefore, there is an association between these K recommended proposals and the recommended proposal used to generate them. That is, the recommended proposal in a previous iteration can be viewed as a parent node to the K recommended proposals in the subsequent iteration.

In step 418, interior furnishing device 204 may optimize each furnishing plan, e.g., by adjusting the placement positions and orientations of the furnishing items in the furnishing plan based on some predetermined furnishing criteria and the structural data of the target room. In some embodiments, the furnishing criteria may include wall touching, floor touching, and retaining a gap between items, etc. Wall touching means an item placed against a wall must touch the wall and floor touching means the item must touch the floor. A sufficient gap should be retained between every two furnishing items to enable a resident to pass through the gap. Otherwise, the gap should be closed. For example, if two adjacent items have a small gap in the middle that not enough for passage, the two items will be adjusted closer together to eliminate the gap.

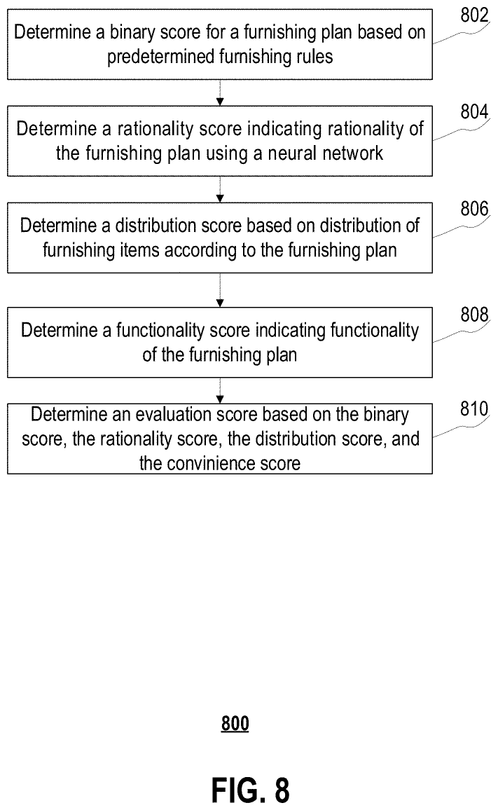

In step 420, interior furnishing device 204 may perform a screening process on the optimized furnishing plans based on certain predetermined plan screening rule. Furnishing plans can be evaluated manually or automatically according to the screening rules. In some embodiments, the plan screening rules can include dispositive rules, and non-compliant furnishing plans may be excluded. In some other embodiments, evaluation scores may be generated for the respective furnishing plans and those with high evaluation scores are recommended first. Exemplary methods for calculating such evaluation scores are described in connection with FIGS. 8-12.

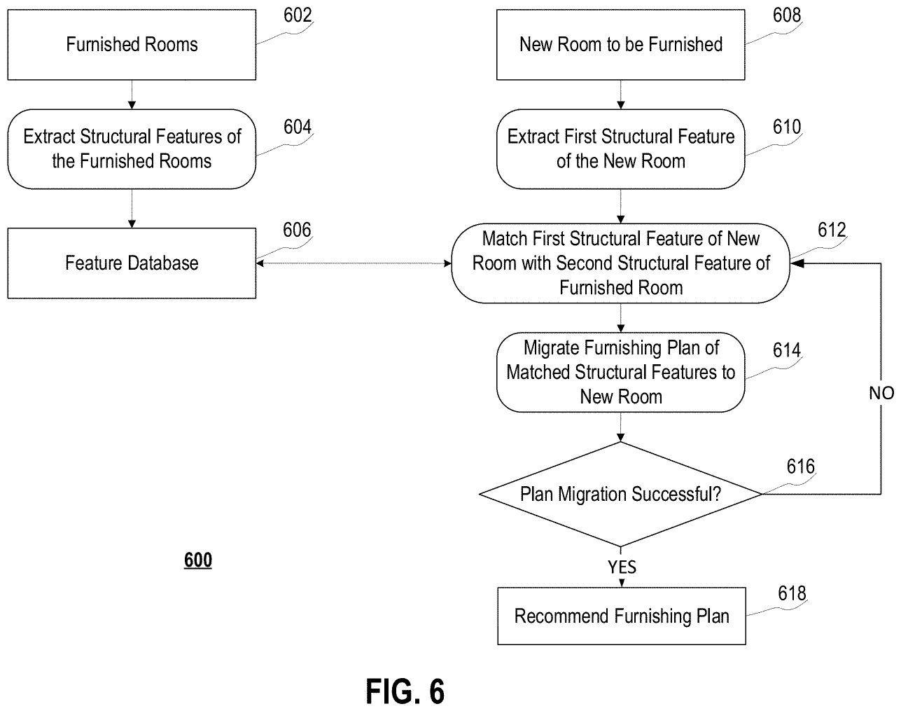

FIG. 6 is a flowchart of an exemplary method for generating a furnishing plan for an interior space using data migration, according to embodiments of the disclosure. In some embodiments, method 600 may also be implemented by model training device 202 and interior furnishing device 204. Method 600 may include steps 602-618 as described below. In some embodiments, steps 602-606 are performed by model training device 202 and steps 608-618 are performed by furnishing plan generation unit 340 of interior furnishing device 204. It is to be appreciated that some of the steps may be optional to perform the disclosure provided herein. Further, some of the steps may be performed simultaneously, or in a different order than shown in FIG. 6. For example, steps 602-606 may be performed in advance and off-line, before steps 608-618 are performed.

In step 602, model training device 202 receives data of furnished rooms. For example, the data of furnished rooms may be stored in training database 201 as training data 210. Furnished rooms are rooms that have been properly furnished with furnishing items, e.g., by professional designers. The data of furnished rooms may include diagrams showing the placement of various furnishing items in the respective rooms and attributes of the furnishing items.

In step 604, model training device 202 extracts structural features and labeled furnishing data associated with the structural features from the data of furnished rooms. Extraction of structural features in step 604 is similar to what is described below in connection with step 610.

In step 606, model training device 202 stores the extracted data (e.g., room furnishing data 214) in a separate database (e.g., feature database 203). For example, each room furnishing data 214 may include the structural features of a previously furnished room and the furnishing data of that furnished room. In some embodiments, room furnishing data 214 may be stored in sub-databases according to room types. For example, each sub-database in feature database 203 may correspond to one room type roomtype, e.g., living room, bedroom, balcony, etc.

In step 608, interior furnishing device 204 receives a floor plan containing at least one room to be furnished. For example, floor plan 216 of property 100 may be received from user device 205. As shown in FIG. 1, property 100 has a living room 110, a kitchen 120, three bedrooms 130, 132, and 134, a bathroom 140, and a balcony 150, etc. Among the rooms, living room 110 has not been furnished yet, and the remaining six rooms or functional spaces have been furnished. Therefore, the new room waiting to be furnished is living room 110.

In step 610, interior furnishing device 204 extracts a structural feature of the new room. These structural feature is referred to as “first structural feature” in the descriptions below to distinguish from those structural features of furnished rooms (referred to as “second structural features”). In some embodiments, structural features may include a plurality of profile feature data arranged in sequence. In general, the outline of a single room can be approximated with a polygon. Accordingly, the structural features of the room can be extracted as following:

(1) starting from any vertex of the polygon, traverse the profile lines of the polygon along a selected direction (e.g., clockwise or counterclockwise);
(2) for each profile line, first record the length, then record the direction (e.g., horizontal or vertical), and finally record positions of all points on this profile line (including two end points and end points of all objects embedded in the walls) in the order of traversal. For example, the starting point position is recorded as 0, the ending point position is recorded as 1, and the intermediate point positions are recorded as between 0 and 1. In some embodiments, the types of structures between every two end points are also recorded, such as walls, doors, windows, passageways, etc. Profile feature data of each profile line can be determined according to the information recorded for each profile line. For example, the profile feature data of the lower profile line of living room 110 in FIG. 1 can be expressed as: [3 meters, horizontal, [0, wall, 0.2, sliding door, 0.8, wall, 1.0]], where “3 meters” is the length of the lower profile line of the living room, “horizontal” indicates the direction of the lower profile line, and “[0, wall, 0.2, sliding door, 0.8, wall, 1.0]” are the ratios of profile structures, indicating the positions of the walls and the sliding door.
(3) form a list with the profile feature data of all the profile lines of the polygon arranged in the order of traversal. The formed list can be used as the structural feature of the single room.

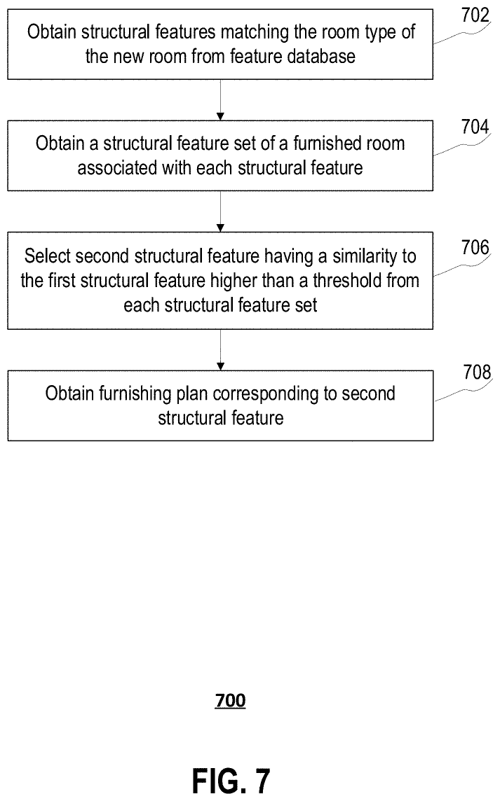

In step 612, interior furnishing device 204 matches the first structural feature with at least one second structural feature of a furnish room stored in feature database 203. For example, FIG. 7 is a flowchart of an exemplary method 700 for matching structural features extracted from an interior space, according to embodiments of the disclosure. In some embodiments, interior furnishing device 204 may perform method 700 to implement step 612 of method 600. Method 700 may include steps 702-708 as described below. It is to be appreciated that some of the steps may be optional to perform the disclosure provided herein. Further, some of the steps may be performed simultaneously, or in a different order than shown in FIG. 7.

In step 702, interior furnishing device 204 obtains structural features matching the room type of the new room from the feature database. For example, based on the room type of the new room (e.g., living room), interior furnishing device 204 queries the corresponding sub-database for that room type in feature database 203. The room type roomtype may include, but is not limited to, a bedroom type, a living room type, a hallway type, a study room Type, a bathroom type, a kitchen type, a dinning room type or a balcony type.

In step 704, interior furnishing device 204 determines a respective structural feature set of a furnished room associated with each structural feature obtained from the feature database. In some embodiments, a structural feature set associated with a structural feature includes any structural feature, and any structural feature obtained after adjusting the order of the profile feature data.

Using the example described in step 610, the structural feature for the new room (e.g., living room 110) includes five profile features arranged in sequence, which are A, B, C, D, and E (assuming it starts from A and traverses in a counterclockwise direction). The five structural features in this structural feature can be re-ordered when determining the structural feature set associated with this structural feature. For example, the structural feature set may include the following re-ordered structural feature B, C, D, E, A (which starts from B and traverses the profile lines in a counterclockwise direction), or structural feature C, D, E, A, B (which starts from C and traverses in a counterclockwise direction), or structural feature D, E, A, B, C (which starts from D and traverses in a counterclockwise direction), or structural feature E, A, B, C, D (which starts from E and traverses in a counterclockwise direction), or structural feature E, D, C, B, A (which starts from E and traverses in a clockwise direction), etc. Each structural feature in the determined structural feature set corresponds to the same room, although the traversal starting point and/or traversal direction can be different.

In step 706, interior furnishing device 204 selects a second structural feature that has a similarity to the first structural feature higher than a predetermined threshold, from the determined structural feature set. In some embodiments, the predetermined threshold may be set as 75%, 80%, 90%, or 95%. It is contemplated that the predetermined threshold is not limited to these exemplary values.

In some embodiments, to identify the second structure feature among the structural feature set, interior furnishing device 204 may first select structural features whose number of profile feature data is the same as that of the first structural feature. Then each selected structural feature may be evaluated in multiple evaluation dimensions. For example, interior furnishing device 204 may calculate an error between the structural feature and the first structural feature in each evaluation dimensions. For example, the error may be a difference between the structural feature and the first structural feature. Consistent with some embodiments, the multiple evaluation dimensions include an angle evaluation dimension, a profile line length evaluation dimension, and a profile structure ratio evaluation dimension, etc. For example, the “multiple” evaluation dimensions may include 2, 3, or more dimensions. A similarity between each selected structural feature and the first structural feature is then determined according to the errors in the multiple evaluation dimensions. The structural feature with a corresponding similarity greater than the predetermined threshold is then identified.

In one example, the first structural feature includes A1, B1, C1, D1, E1 arranged in sequence (assuming it traverses in a counterclockwise direction), and a selected structural feature includes A2, B2, C2, D2, E2 (assuming it also traverses in a counterclockwise direction). Using three evaluation dimensions (angle, profile line length, and profile structure ratio), three errors can be calculated for the selected structural feature.

A first error S1 in the angle evaluation dimension can be calculated based on the directional errors for the five profile lines. For example, the directional error for the first profile line is a difference between the angle theta1 formed between A1 and B1 and the angle theta2 formed between A2 and B2 is. If the difference exceeds a predetermined value, the direction error determined according to (A1, B1, A2, B2) is set to be 1. If the difference is equal to 0, the direction error is set to 0. If the difference is between 0 and the predetermined value, the direction error is set between 0 and 1. Directional errors can be similarly determined for (B1, C1, B2, C2), (C1, D1, C2, D2), (D1, E1, D2, E2), and (E1, A1, E2, A2). The five directional error values can be merged to obtain the first error S1 in angle evaluation dimension. For example, the maximum value of the five directional error can be used as the error S1 in the angle evaluation dimension.

A second error S2 in the profile line length evaluation dimension can be calculated based on the length errors for the five profile lines. For example, the length error for the first profile line can be calculated as a ratio k1=(L12−L11)/max (L11, L12), where L11 is the profile line length of A1 and L12 is the profile line length of A2. If k1 exceeds a predetermined ratio (e.g., 20%), the length error determined between A1 and A2 is set to be 1. If k1 is equal to 0, the length error is set to be 0. If k1 is between 0 and the predetermined ratio, the length error is set between 0 and 1. Length errors can be similarly determined for (B1, B2), (C1, C2), (D1, D2), and (E1, E2). Then the five length errors can be merged to obtain the second error S2 in the profile line length evaluation dimension. For example, the maximum value of the five length errors can be used as the error S2 in the profile line length evaluation dimension.

A third error S3 in the profile structure ratio evaluation dimension can be calculated based on the structure ratio errors for the five profile lines. For example, if the profile structure ratios of A1 and A2 are identical, the error between A1 and A2 is set to be 0. If the profile structure ratio of A1 is [0, wall, 0.2, sliding door, 0.8, wall, 1.0], and the profile structure ratio of A2 is [0, wall, 0.3, sliding door, 0.7, wall, 1.0], the unmatched sections are 0.20.3 and 0.70.8, and the total difference in the two sections is 0.2 (or 20%) of the total length of the profile line. Errors in structure ratios can be similarly determined for (B1, B2), (C1, C2), (D1, D2), and (E1, E2). Then the five structural ratio errors can be merged to obtain the third error S3 in the profile structure ratio evaluation dimension. For example, the five structural ratio errors can be summed. If the sum is less than or equal to 1, the sum is used as the error S3 in the profile structure ratio evaluation dimension. If the sum is greater than 1, error S3 is set to be 1.

In one example, based on S1, S2, and S3 calculated above, the similarly S can be calculated as S=1−(S1+S2+S3)/3. S is then compared with the predetermined threshold. The structural feature with a similarly S greater than the predetermined threshold can be identified and selected as the second structural feature. By calculating the errors in multiple evaluation dimensions, the accuracy and reliability of the calculated similarities can be improved, thereby ensuring that the selected second structural feature meets the requirements.

In step 708, interior furnishing device 204 obtains an actual furnishing plan of a furnished room corresponding to the second structural feature. In some embodiments, the structural feature and its corresponding furnishing plan may be stored in a pair in feature database 203. Interior furnishing device 204 can query feature database 203 to obtain the actual furnishing plan. The actual furnishing plan may include labeled furnishing data indicating what furnishing items are placed in the room and how they are placed (e.g., their positions and orientations).

Returning to FIG. 6, in step 614, interior furnishing device 204 performs an attempted migration operation for migrating the actual furnishing plan of the furnished room to the room to be furnished to create a reference furnishing plan. In some embodiments, interior furnishing device 204 first determines the relative position transformation information between the room to be furnished and the furnished room. The relative position transformation information may include, e.g., flip information indicating the type of flipping needed, rotation information such as the angle of rotation, and translation information such as the distance of the translation. In some embodiments, to determine the relative position transformation information, interior furnishing device 204 determines the profile of a furnishing item and whether/how any of the profile lines is against any wall in the furnished room. For example, a bounding box enclosing the furnishing item can be determined as its profile and the four sides of the bounding box are the profile lines. For example, a reference point 1 can be determined in the furnished room, and the reference point 1 is migrated to a reference point 2 in the new room. The relative position transformation information, such as the flip information bFlip, rotation information angle and translation information delta, can be determined based on the coordinates of reference point 1 and reference point 2.

According to the relative position transformation information, each furnishing item in the actual furnishing plan of the furnished room can be migrated to the new room, by flipping, rotating, and/or translating the furnished item. After the migration, if the profile and wall information of any furnishing item in the new room is different from that in the furnished room, interior furnishing device 204 can adjust the position of the furnishing item in the new room until the profile and wall information of the item is consistent with that in the furnished room. For example, if the right profile line of the furnishing item is against a wall in the furnished room, but the migrated furnishing item in the new room is not against a wall on the right profile line, interior furnishing device 204 may move the furnishing item rightward until it hits a wall or move it leftward until it hits a wall if there is no wall found in the new room right to the item. Once all furnishing items in the actual furnishing plan are migrated and adjusted, if necessary, interior furnishing device 204 creates a reference furnishing plan for the new room based on the placement positions and orientations of the furnishing items in the new room.

In step 616, interior furnishing device 204 determines whether the migration of furnishing plan is successful. In some embodiments, the migration is considered successful if the reference furnishing plan of the new room complies with certain predetermined furnishing rules. The predetermined furnishing rules include at least one of no floating furnishing item, no blocking of any opening of the room, such as doors and/or windows. An item is considered “floating” if any profile line of the item partially hangs in the air. For example, if a furnishing item is partially against the wall on one profile line and partially hangs in the air, it violates the no floating rule and thus does not comply with the predetermined furnishing rules. As another example, if the furnishing item partially blocks a door or a window, it violates the no blocking rule and thus does not comply with the predetermined furnishing rules.

If the migration is found unsuccessful (step 616: NO), method 600 will return to step 612 to match the first structure feature with a different second structure feature in feature database 203. If the migration is found successful (step 616: YES), in step 618, interior furnishing device 204 determines the recommend furnishing plan of the room according to the reference placement plan. Interior furnishing device 204 may provide the recommended furnishing plan to user device 205 to be displayed to the user (e.g., a property owner). The recommended furnishing plan may be provided in various forms, e.g., through an email, placing to a shared storage, or in the form of image, video, or audio data.

It is contemplated that in step 612 the first structural feature can be matched with more than one second structural features corresponding to more than one furnished rooms. For example, there are structural features of multiple furnished living rooms in feature database 203. The structural features of various furnished rooms that are sufficiently similar to the first structural feature can be identified as the second structural features. Accordingly, more than one actual furnishing plans of the furnished rooms corresponding to the second structural features will be migrated in step 614 to create more than one reference furnishing plans. More than one recommended furnishing plans can be resulted from these reference furnishing plans. In some embodiments, interior furnishing device 204 may provide all the recommended furnishing plans to user device 205. In some alternative embodiments, interior furnishing device 204 may evaluate the recommended furnishing plans, rank them based on the evaluation, and provide only the highest-ranked plan to user device 205. Exemplary methods for calculating evaluation scores for furnishing plans are described in connection with FIGS. 8-12.

In one exemplary embodiment, methods 600 and 700 can be applied to furnish living room 110 (referred to as room1) in FIG. 1. In step 610, first structural feature lf1 of room1 is extracted, e.g., based on traversing the profile of a polygon. In step 612, the first structural feature lf1 is matched with a second structural feature lf2. Specifically, in step 702, structural features lf2 all of furnished living rooms are obtained from feature database 203. In step 704, structural feature sets lf2_set corresponding to the structural features lf2 are obtained. lf2_set includes lf2_all, as well as re-arranged structural features for different profile traversal operations (e.g., from different starting vertices and/or in different traversal directions). In step 706, any given structural feature (e.g., lf2_0) in lf2_set has a different number of profile lines compared to lf1, the similarity is 0 and it is not a match. If lf2_0 and lf1 has the same number of profile lines, a similarity is calculated based on the profile feature data of lf2_0 and lf1. The structural feature lf2 that has a similarity exceeding a predetermined threshold is identified as the second structural feature. Assuming structural feature lf2 is extracted from a furnished room referred to as room2, room1 and room2 are also considered matched. In step 708, the actual furnishing plan of room2 is obtained. In step 614, migration from the actual furnishing plan of room2 to a reference furnishing plan of room1 is attempted. The migration can be implemented by flipping, rotating, and/or translating the labeled furnishing data of the actual furnishing plan based on the relative position transformation information determined between room1 and room2, such as flip information bFlip, rotation information angle and translation information delta. Each migrated furnishing item may be further adjusted in room1 to ensure the reference furnishing plan for room1 matches the actual furnishing plan for room2. If the migration of the furnishing plan is successful (step 616: YES), a recommended furnishing plan is created for room1 and provided to the user device.

FIG. 8 is a flowchart of an exemplary method 800 for evaluating a furnishing plan for an interior space, according to embodiments of the disclosure. In some embodiments, method 800 may be performed by processor 304 of interior furnishing device 204, e.g., furnishing plan evaluation unit 342. Method 800 may include steps 802-810 as described below. It is to be appreciated that some of the steps may be optional to perform the disclosure provided herein. Further, some of the steps may be performed simultaneously, or in a different order than shown in FIG. 8.

Method 800 can be performed to determine an evaluation score for a furnishing plan of a target room, thus evaluating the furnishing plan. For example, the furnishing plan may be automatically generated by furnishing plan generation unit 340 by performing method 400 or method 600. In some embodiments, method 800 may evaluate different aspects of the floor plan based on different evaluation standards. As a result, method 600 may generate different evaluation scores for the different aspects evaluated, and then determine the overall evaluation score collectively based on those scores.

In step 802, interior furnishing device 204 calculates a binary score for the furnishing plan of a target room based on one or more predetermined furnishing rules of the placement plan. The binary score indicates whether the furnishing plan complies with the predetermined furnishing rules. The target room can be a bedroom, a living room, a bathroom, etc. One or more furnishing items are placed in the target room according to the furnishing plan. The furnishing items include, e.g., furniture pieces, fixtures, appliances, and decorations, etc. A furnishing plan may include a placement diagram for showing the placement and orientation of the furnishing items.

In some embodiments, the predetermined furnishing rules include no overlapping of furnishing items, no penetration of walls, no blocking pathways, etc. Interior furnishing device 204 can determine whether the furnishing plan meets the furnishing rules using computer vision technology or the like. If all the rules are met, the binary score is set to 1, and otherwise, the binary score is set to 0. The furnishing rules are rigid rules that must be met by the furnishing plan. Therefore, if any one rule is not met, the binary score will be 0.

In step 804, interior furnishing device 204 calculates a rationality score for the furnishing plan using a neural network. The rationality score indicates the rationality of the furnishing plan. In some embodiments, the rationality score can be determined by applying the neural network to the structural features of the target room, attributes of the furnishing items placed in the target room, and the placement information of these items according to the furnishing plan. The structural features include wall distribution data of the floor plan, load-bearing wall distribution data, door and window distribution data, area data, story height data, and position coordinate data, etc. Attributes of a furnishing item include item category, item style, item size, item placement attributes, etc. Placement information of a furnishing item includes item placement position, orientation, whether the item must be against the wall, whether the item has a front area, and whether the item can enter the front area of any other item, etc.

The neural network may be part of learning models 212 trained by model training device 202 using training data 210 provided by training database 201. Different types of neural network models, such as a graphical neural network GNN (Graphical Neural Network) model, can be used. In some embodiments, the GNN network can be trained based on a fixed-point query algorithm (Position Query). The GNN model outputs a rationality score indicating how likely the furnishing plan will be recommended for the target room.

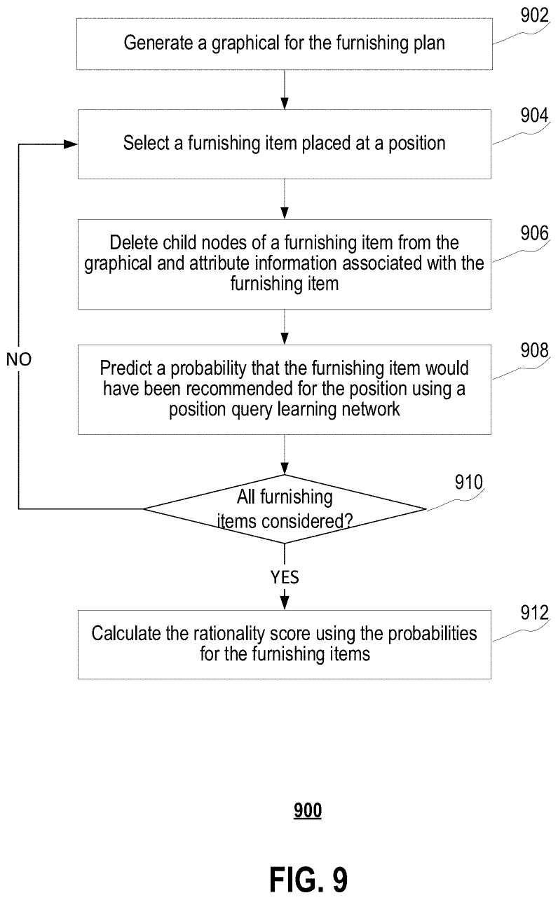

FIG. 9 is a flowchart of an exemplary method 900 for generating a rationality score for a furnishing plan, according to embodiments of the disclosure. In some embodiments, method 900 may be performed by processor 304 of interior furnishing device 204, e.g., furnishing plan evaluation unit 342. Method 900 may be performed to implement step 804 to calculate the rationality score. Method 900 may include steps 902-912 as described below. It is to be appreciated that some of the steps may be optional to perform the disclosure provided herein. Further, some of the steps may be performed simultaneously, or in a different order than shown in FIG. 9.

In step 902, interior furnishing plan may generate a graphical for the furnishing plan. The graphical may be a computer diagram showing the various furnishing items placed in a floor plan of the target room according to the furnishing plan. For example, the graphical specifies the placement positions and orientations of the items, as well as the parent-child relationship between the items. For example, in the graphical, an item is the parent node to all items placed after it and conversely, an item is a child node to another item placed before it. All the furnishing items in the furnishing plan can be placed in a list list-furnitures.

In step 904, interior furnishing device 204 selects a furnishing item from list_furnitures. The furnishing item can be located in the graphical generated in step 902. In step 906, interior furnishing device 204 deletes all child nodes of the selected furnishing item in the graphical. It further deletes certain attributes of the selected furnishing item, such as item category, item size, etc. However, the item position information will be preserved. In step 906, interior furnishing device 204 predicts a probability that the selected furnishing item would have been recommended to be placed at the position using the neural network. Method 900 returns to step 904 and repeats steps 904-908 for the next furnishing item on list_furnitures until all the items on the list are considered (step 910: YES).

In steps 912, interior furnishing device 204 calculates the rationality score based on the probabilities for all the furnishing items on list_furnitures. There are different ways to concatenate the probabilities into the rationality score. For example, the rationality score may be the average or mean value of the probabilities, a sum of the probabilities, or a weighted sum of the probabilities. For example, certain furnishing items may be more essential than others and therefore their probabilities will be weighted more heavily than other items. For instance, a bed is considered more essential than a mirror in a bedroom.

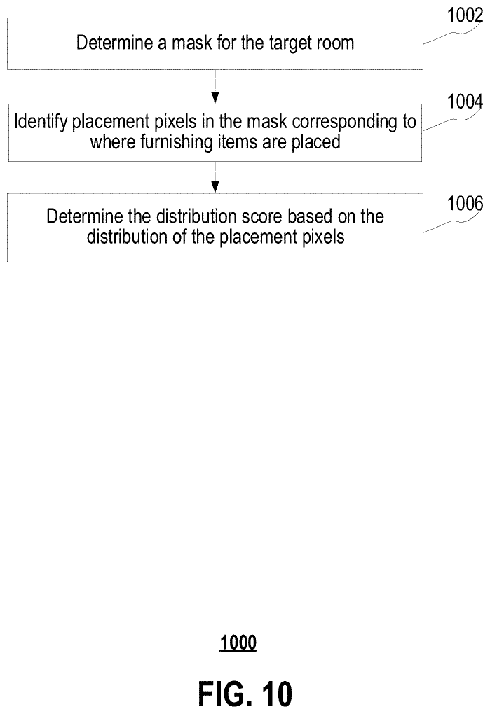

Returning to FIG. 8, in step 806, interior furnishing device 204 determines a distribution score based on the distribution of furnishing items, according to the furnishing plan. The distribution score indicates the uniformity the overall distribution of furnishing items in the target room. For example, FIG. 10 is a flowchart of an exemplary method 1000 for generating a distribution score for a furnishing plan, according to embodiments of the disclosure. In some embodiments, method 1000 may be performed by processor 304 of interior furnishing device 204, e.g., furnishing plan evaluation unit 342. Method 1000 may be performed to implement step 806 to calculate the distribution score. Method 1000 may include steps 1002-1006 as described below. It is to be appreciated that some of the steps may be optional to perform the disclosure provided herein. Further, some of the steps may be performed simultaneously, or in a different order than shown in FIG. 10.

In step 1002, interior furnishing device 204 determines a mask for the target room. The mask may be generated using structural features associated with the floor plan of the room, the attributes of the furnishing items placed in the target room, and the placement information of the furnishing items according to the furnishing plan. The mask is an image that has the same image size (e.g., number of pixels) as the floor plan of the target room. The mask reflects the structural features of the floor plan and furnishing items placed in the floor plan. In some embodiments, the value of each pixel in the mask takes a binary value, e.g., either 0 or 255. For example, if the value of a certain pixel is 0, the corresponding position is unoccupied by any furnishing item. Otherwise, if the value of a certain pixel is 255, the corresponding position is occupied by an existing furnishing item.

In step 1004, interior furnishing device 204 identifies placement pixels in the mask corresponding to where the furnishing items are placed. For example, the placement pixel corresponding to the placement position of a furnishing item can be the gravity center or the geometric center point of the item. The placement pixels of the furnishing items indicate the distribution of these items in the floor plan.

In step 1006, interior furnishing device 204 determines a distribution of the placement pixels and determines the distribution score based on the distribution. In some embodiments, the distribution score is an indicator of the uniformity of the distribution of furnishing items in the target room. The indicator favors a more uniform distribution. For example, when the items are uniformly distributed, the distribution score is larger. When the items cluster together in one area of the target room and thus leaving a lot of empty space elsewhere, the distribution score is smaller.

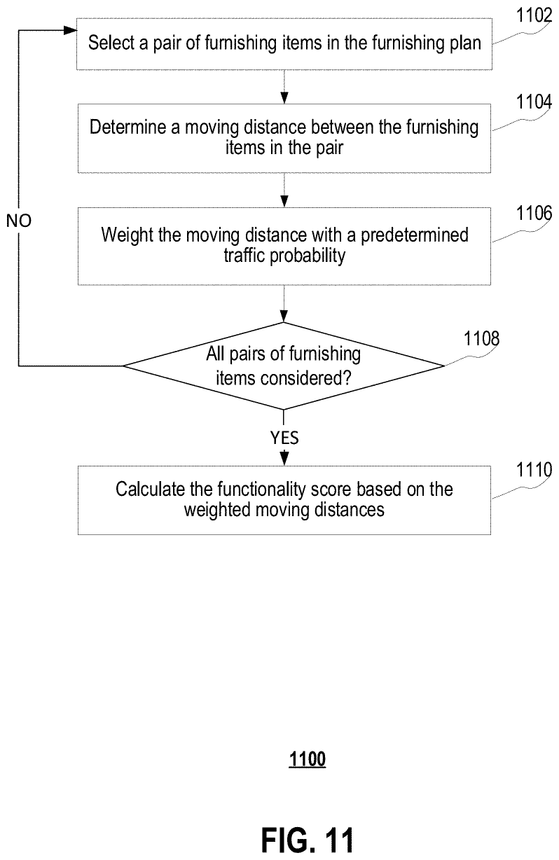

Returning to FIG. 8, in step 808, interior furnishing device 204 determines a functionality score indicating the functionality of the furnishing plan. In some embodiments, the functionality of the furnishing plan is measured by the mobility of a resident in the target room furnished according to the furnishing plan. For example, FIG. 11 is a flowchart of an exemplary method 1100 for generating a functionality score for a furnishing plan, according to embodiments of the disclosure. In some embodiments, method 1000 may be performed by processor 304 of interior furnishing device 204, e.g., furnishing plan evaluation unit 342. Method 1100 may be performed to implement step 806 to calculate the distribution score. Method 1100 may include steps 1102-1110 as described below. It is to be appreciated that some of the steps may be optional to perform the disclosure provided herein. Further, some of the steps may be performed simultaneously, or in a different order than shown in FIG. 11.

In some embodiments, method 1100 may include steps 1002 and 1004 of method 1000 to generate a mask for the target room and identify the placement pixels of the furnishing items placed in the mask. In step 1102, interior furnishing device 204 selects a pair of furnishing items in the furnishing plan. For example, the selected pair may include a bed and a dresser. In step 1104, interior furnishing device 204 determines a moving distance between the furnishing items in the pair. In some embodiments, the moving distance can be determined based on the placement pixels of the furnishing items in the mask. The moving distance between the two furnishing items may be the distance a person has to travel from one item to the other. In other words, the moving distance is not a linear distance between the two items, but a length of a pathway between them.

In step 1106, interior furnishing device 204 weights the moving distance with a predetermined weight. In some embodiments, the weight is a probability of traffic, i.e., how often the pathway between the two items in the pair is used by residents in the room. For example, the weight is higher when the items are in a high-traffic area of the room. Interior furnishing device 204 repeats steps 1102-1106 for each pair of furnishing items in the furnishing plan until all pairs are considered (step 1108: YES).

In step 1108, interior furnishing device 204 calculates the functionality score based on the weighted moving distances. In some embodiments, the functionality score can be a weighted average of the moving distances. For example, there are three furnishing items A, B, and C in the furnishing plan, the moving distances of the three pathways between every two items are 3, 4, and 5 respectively, and the traffic probabilities corresponding to the three pathways are 0.3, 0.5, and 0.6. The traffic probabilities can be used as weight coefficients for the three pathways. Accordingly, the functionality score can be determined as the weighted average of moving distances, as (3*0.3+4*0.4+5*0.6)/3=1.83.

Returning to FIG. 8, in step 810, interior furnishing device 204 determines the evaluation score based on the various scores calculated in steps 802-808. In some embodiments, because the predetermined furnishing rules used for determining the binary score are rigid rules, a furnishing plan that receives a 0 binary score should be removed and not recommended to a user. Therefore, the binary score should be dispositive to the evaluation score. In some embodiments, the other scores may be weighted and reflected in the evaluation score. In one example, the evaluation score can be determined as s=s1*(s2+k3*s3+k4*s4), where s1 is the binary score, s2 is the rationality score, s3 is the distribution score, s4 is the functionality score, and k3 and k4 are weighting coefficients. Accordingly, if binary score s1=0, evaluation score s=0 regardless of the other scores. When s1=1, s is a weighted sum of rationality score s2, distribution score s3, and functionality score s4.

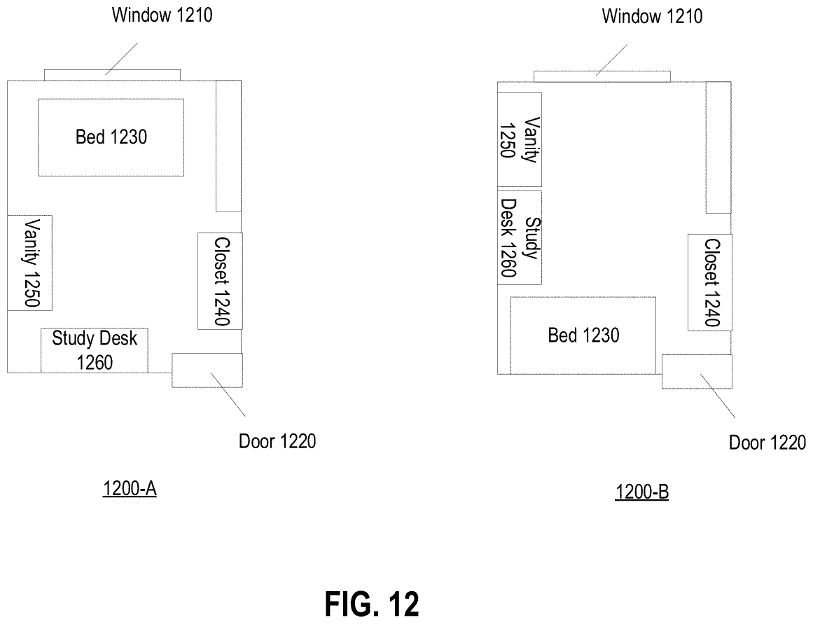

FIG. 12 illustrates schematic diagrams of two different furnishing plans 1200-A and 1200-B for a same interior space, according to embodiments of the disclosure. As shown in FIG. 12, the target room includes structures such as a window 1210, a door 1220, and walls, etc. Various of furnishing items are placed in the target room. For example, furnishing items include list_furnitures=[“bed 1230”, “closet 1240”, “vanity 1250”, “study desk 1260”]. These furnishing items are placed differently in furnishing plan 1200-A and 1200-B. For example, in furnishing plan 1200-A, bed 1230 is placed next to window 1210, closet 1240 is placed near door 1220 and against a right wall, vanity 1250 is placed against another wall opposite to the wall of closet 1240, and study desk 1260 is placed against the wall opposite to the wall having window 1210 and near door 1220. In furnishing plan 1200-B, bed 1230 is placed against the wall opposite window 1210 and next to door 1220, closet 1240 is placed near door 1220 and against a right wall, vanity 1250 and study desk 1260 are placed against another wall opposite to the wall of closet 1240 and next to each other.

In some embodiments, methods 800-1100 can be applied to evaluate the two furnishing plans. For example, for each furnishing plan 1200-A or 1200-B, a binary score s1 can be determined based on whether the furnishing plan complies with all the predetermined furnishing rules. Method 900 can be applied to determine a rationality score s2 for each furnishing plan using a neural network, such as a GNN model which predicts the probability of each furnishing item to be placed at the position indicated by the furnishing plan. Method 1000 can be applied to determine a distribution score s3 for each furnishing plan, which measures how uniform the furnishing items are distributed in the furnishing plan. Method 1100 can be applied to determine a functionality score s4 for each furnishing plan, which can be a weighted average of moving distances between every two furnishing items in the furnishing plan. A final evaluation score can be determined for each furnishing plan 1200-A or 1200-B based on their respective scores s1, s2, s3, and s4. For example, the final score s is calculated as s=s1*(s2+k3*s3+k4*s4), where k3 are k4 are weighting coefficients. The furnishing plan that has a higher final score may be recommended to the user.

Between furnishing plan 1200-A and furnishing plan 1200-B, furnishing plan 1200-A will likely have a higher evaluation score. In both furnishing plans, assuming no furnishing rule is to be violated, then s1=1. The item placement in furnishing plan 1200-A is more reasonable, the distribution of the furnishing items is more uniform, and the overall moving distances may be shorter, and therefore the weighted sum of s2, s3, and s4 for furnishing plan 1200-A is likely larger. Therefore, the evaluation score of furnishing plan 1200-A may be larger. As a result, furnishing plan 1200-A is more likely recommended to the user to assist furnishing the target room. In some embodiments, both furnishing plans may be provided to the user with the respective evaluation scores.

Another aspect of the disclosure is directed to a non-transitory computer-readable medium storing instruction which, when executed, cause one or more processors to perform the methods, as discussed above. The computer-readable medium may include volatile or non-volatile, magnetic, semiconductor, tape, optical, removable, non-removable, or other types of computer-readable medium or computer-readable storage devices. For example, the computer-readable medium may be the storage device or the memory module having the computer instructions stored thereon, as disclosed. In some embodiments, the computer-readable medium may be a disc or a flash drive having the computer instructions stored thereon.

Although the embodiments are described using interior design of indoor spaces as examples, it is contemplated that the concepts could be readily expanded and adapted to design of outdoor spaces, such as the deck, the front/back yard, the garage, as well as the neighboring environment. A person of ordinary skill can adapt the disclosed systems and methods without undue experimentation for outdoor designs.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

1. A system for generating a furnishing plan for a property, comprising:
a communication interface configured to receive a floor plan of the property, at least one candidate furnishing item to be placed in the property and attributes of the candidate furnishing item, and a first neural network model; and
at least one processor configured to:
generate a mask based on the floor plan of the property and the attributes of the candidate furnishing item;
generate proposals for placing the candidate furnishing item in the property based on the mask and the attributes of the candidate furnishing item;
determine a probability for each proposal using the first neural network model, wherein the first neural network model is trained with a position query algorithm;
select one or more proposals having the highest probabilities; and
generate the furnishing plan for the property based on the one or more proposals.

2. The system of claim 1, wherein the first neural network model is a Graph Neural Network (GNN).

3. The system of claim 1, wherein the communication interface is further configured to receive attributes of at least one existing furnishing item in the property, wherein the at least one processor is configured to generate the mask additionally based on the attributes of the existing furnishing item.

4. The system of claim 1, wherein the mask comprises a plurality of pixels each having either a first value or a secondary value, the first value indicating the corresponding pixel is not available for placing the candidate furnishing item and the second value indicating the corresponding pixel is available for placing the candidate furnishing item.

5. The system of claim 4, wherein to generate proposals for placing the candidate furnishing item in the property based on the mask and the attributes of the candidate furnishing item, the at least one processor is further configured to:
select discrete pixels in the mask that each have the second value; and
generate the proposals for placing the candidate furnishing item at the selected discrete pixels.

6. The system of claim 1, wherein the at least one processor is further configured to:
rank the proposals based on the respective probabilities; and
select the one or more proposals with the highest probabilities according to the ranking, wherein the one or more proposals include the proposal with the highest probability and one or more proposals having probabilities differing from the highest probability with less a threshold difference.

7. The system of claim 1, wherein for each selected proposal, the at least one processor is further configured to:
generate a new mask based on the floor plan of the property, attributes of the candidate furnishing item placed according to the selected proposal, and the attributes of a new candidate furnishing item;
generate proposals for placing the new candidate furnishing item in the property based on the new mask and the attributes of the new candidate furnishing item;
determine a probability for each proposal using the first neural network model; and
select one or more proposals having the highest probabilities.

8. The system of claim 1, wherein the communication interface is further configured to receive a second neural network model, wherein the at least one processor is further configured to:
calculate a rationality score for the furnishing plan based on the second neural network model, wherein the second neural network model is trained with a position query algorithm.

9. The system of claim 8, wherein to calculate the rationality score for the furnishing plan, the at least one processor is further configured to:
generate a graphical for the furnishing plan;
for each furnishing item placed at a position according to the furnishing plan, predict a probability that the furnishing item would have been recommended to be placed at the position using the second neural network model; and
calculate the rationality score based on the probabilities of the furnishing items in the furnishing plan.

10. The system of claim 9, wherein the at least one processor is further configured to:
calculate a binary score for the furnishing plan based on one or more predetermined furnishing rules;
calculate a distribution score based on a distribution of furnishing items according to the furnishing plan; and
calculate a functionality score indicating a functionality of the furnishing plan.

11. The system of claim 10, wherein to calculate the distribution score, the at least one processor is further configured to:
generate a furnished mask for the furnishing plan;
identify placement pixels in the furnished mask corresponding to where the furnishing items are placed according to the furnishing plan; and
determine the distribution score based on a distribution of the placement pixels.

12. The system of claim 10, wherein to calculate the functionality score, the at least one processor is further configured to:
for each pair of furnishing items in the furnishing plan, determine a moving distance between the furnishing items in the pair; and
determine the functionality score based on the moving distances weighted by predetermined weights.

13. The system of claim 10, the at least one processor is further configured to calculate an evaluation score for the furnishing plan, wherein the evaluation score is a weighted sum of the rationality score, the distribution score, and the functionality score, which is further weighted by the binary score.

14. A computer-implemented method for generating a furnishing plan for a property, comprising:
receiving, by communication interface, a floor plan of the property, at least one candidate furnishing item to be placed in the property, and attributes of the candidate furnishing item, and a first neural network model;
generating, by at least one processor, a mask based on the floor plan of the property and the attributes of the candidate furnishing item;
generating proposals for placing the candidate furnishing item in the property based on the mask and the attributes of the candidate furnishing item;
determining, by the at least one processor, a probability for each proposal using the first neural network model, wherein the first neural network model is trained with a position query algorithm;
selecting one or more proposals having the highest probabilities; and
generating, by the at least one processor, the furnishing plan for the property based on the one or more proposals.

15. The method of claim 14, wherein the mask comprises a plurality of pixels each having either a first value or a secondary value, the first value indicating the corresponding pixel is not available for placing the candidate furnishing item and the second value indicating the corresponding pixel is available for placing the candidate furnishing item,
wherein generating proposals for placing the candidate furnishing item in the property based on the mask and the attributes of the candidate furnishing item further comprises:
selecting discrete pixels in the mask that each have the second value; and
generating the proposals for placing the candidate furnishing item at the selected discrete pixels.

16. The method of claim 14, further comprising, for each selected proposal:
generating a new mask based on the floor plan of the property, attributes of the candidate furnishing item placed according to the selected proposal, and the attributes of a new candidate furnishing item;
generating proposals for placing the new candidate furnishing item in the property based on the new mask and the attributes of the new candidate furnishing item;
determining a probability for each proposal using the first neural network model; and
selecting one or more proposals having the highest probabilities.

17. The method of claim 14, further comprising:
receiving a second neural network model, wherein the second neural network model is trained with a position query algorithm;
generating a graphical for the furnishing plan;
for each furnishing item placed at a position according to the furnishing plan, predicting a probability that the furnishing item would have been recommended to be placed at the position using the second neural network model; and
calculating a rationality score for the furnishing plan based on the probabilities of the furnishing items.

18. The method of claim 17, further comprising:
calculating a binary score for the furnishing plan based on a predetermined furnishing rules;
calculating a distribution score based on a distribution of furnishing items according to the furnishing plan; or
calculating a functionality score indicating resident mobility of the furnishing plan.

19. The method of claim 18, further comprising calculating an evaluation score for the furnishing plan, wherein the evaluation score is a weighted sum of the rationality score, the distribution score, and the functionality score, which is further weighted by the binary score.

20. A non-transitory computer-readable medium having stored thereon computer instructions, when executed by at least one processor, perform a method for generating a furnishing plan for a property, comprising:
receiving a floor plan of the property, at least one candidate furnishing item to be placed in the property, and attributes of the candidate furnishing item, and a first neural network model;
generating a mask based on the floor plan of the property and the attributes of the candidate furnishing item;
generating proposals for placing the candidate furnishing item in the property based on the mask and the attributes of the candidate furnishing item;
determining a probability for each proposal using the first neural network model, wherein the first neural network model is trained with a position query algorithm;
selecting one or more proposals having the highest probabilities; and
generating the furnishing plan for the property based on the one or more proposals.
